(19) United States
(12) Patent Application Publication
(10) Pub. No.: US 2011/0260060 A1
(43) Pub. Date: Oct. 27, 2011

(54) SYSTEM AND METHOD FOR THERMAL IMAGING SEARCHLIGHT

(76) Inventors: John B. Gunter, Flower Mound, TX (US); Kenneth W. Walling, Wylie, TX (US); Joseph Crenshaw, Dallas, TX (US)

(21) Appl. No.: 13/025,104

(22) Filed: Feb. 10, 2011

Related U.S. Application Data
(60) Provisional application No. 61/303,101, filed on Feb. 10, 2010.

(51) Int. Cl. H01L 27/14; H01L 31/00

(52) U.S. Cl. 250/332; 250/334

(57) ABSTRACT

A searchlight includes a canopy, a thermal-imaging camera, and an infrared (IR) light source. The thermal-imaging camera is mounted within the canopy so that the thermal-imaging camera is operable to move in conjunction with the canopy. The IR light source disposed along a periphery of the canopy.

### CROSS-REFERENCE TO RELATED APPLICATIONS

This application claims priority from, and incorporates by reference the entire disclosure of, U.S. Provisional Application No. 61/303,101 filed on Feb. 10, 2010.

### BACKGROUND

1. Technical Field

The present invention relates in general to thermal imaging, and more particularly, but not by way of limitation, to remotely-controlled searchlights with thermal-imaging capabilities.

2. History of Related Art

Thermal imaging provides a near daylight-quality view of the environment in low visibility conditions such as, for example, darkness or dust storms. Remotely-controlled thermal-imaging devices give a pilot of an aircraft such as, for example, a helicopter, a valuable tool for detecting hidden threats in low-visibility conditions, such as, for example, power lines, trees, broadcast antennas, and obstructions in a landing zone.

Thermal-imaging devices are generally gimbal-mounted onto aircraft. Many gimbal-mounted thermal-imaging cameras are heavy (e.g., 75-150 lbs) and expensive (e.g., some greater than $150,000). This limits their application to platforms that have the requisite budget and payload capacity. Therefore, although incredibly useful, remotely-controlled thermal imaging is infeasible and/or prohibitively expensive for a wide variety of potential applications.

### SUMMARY OF THE INVENTION

In one embodiment, a method includes providing a searchlight operable to mate with a structure, the searchlight comprising a base and a canopy movably attached to the base. The method further includes mounting a thermal-imaging camera within the canopy so that the thermal-imaging camera is operable to move in conjunction with the canopy responsive to an operator control. In addition, the method includes disposing an infrared (IR) light source ring along a periphery of the canopy.

In another embodiment, a searchlight comprises a base, a canopy, a thermal-imaging camera, and an infrared (IR) light source ring. The base includes a drive system and is operable to mate with a structure. The canopy is movably attached to the base and operable to be controlled by the drive system to move responsive to an operator control. The thermal-imaging camera is mounted within the canopy so that the thermal-imaging camera is operable to move in conjunction with the canopy. The IR light source ring is disposed along a periphery of the canopy.

In another embodiment, a searchlight includes a canopy, a thermal-imaging camera, and an infrared (IR) light source. The thermal-imaging camera is mounted within the canopy so that the thermal-imaging camera is operable to move in conjunction with the canopy. The IR light source disposed along a periphery of the canopy.

### BRIEF DESCRIPTION OF THE DRAWINGS

A more complete understanding of the method and apparatus of the present invention may be obtained by reference to the following Detailed Description when taken in conjunction with the accompanying Drawings wherein:

FIG. 1 is a perspective view of an embodiment of a searchlight;

FIG. 2 is a perspective view of an embodiment of a searchlight;

FIG. 3 is a front view of an embodiment of a canopy of a searchlight;

FIG. 4 is a front view of an embodiment of a searchlight;

FIG. 5A illustrates a schematic view of a searchlight;

FIG. 5B illustrates a schematic view of a searchlight; and

FIG. 6 illustrates an exemplary structure having a keyhole slot.

### DETAILED DESCRIPTION OF ILLUSTRATIVE EMBODIMENTS OF THE INVENTION

In various embodiments, thermal-imaging capabilities may be provided to a diverse array of structures. A structure, as used herein, may be a stationary structure or a transport structure. For purposes of this patent application, a stationary structure is a structure that is not generally mobile such as, for example, a port, a station, or a building. For purposes of this patent application, a transport structure includes any land, water, or air-based vessel or vehicle including, but not limited to, water vessels, aircraft, and land-based vehicles (e.g., tanks, trucks, or cars).

For example, in various embodiments, remotely-controlled thermal-imaging capabilities may be provided by integrating a suitable thermal-imaging camera into another remotely-controlled device. As discussed in more detail below, in some embodiments, a suitable thermal-imaging camera may be selected and mated with a remotely-controlled aircraft searchlight in compliance with a specified standard for the remotely-controlled aircraft searchlight. In that way, remotely-controlled thermal imaging may be integrated into a variety of aircraft without any need for heavy and expensive gimbal-mounted thermal-imaging devices.

In some embodiments, remotely-controlled thermal-imaging capabilities may be added to a remotely-controlled searchlight in compliance with a standard specification such as, for example, military specification MIL-L-81174. Military specification MIL-L-81174 is described in a military specification sheet published on Sep. 21, 1972, which is hereby incorporated by reference. The military specification sheet is also attached as Appendix A to U.S. Provisional Application No. 61/303,101, which is also incorporated herein by reference. A “MIL-L-81174-compliant searchlight,” as used herein, refers to a searchlight that satisfies MIL-L-81174 requirements as described herein and in the above-mentioned military specification sheet and is operable to be mated with an aircraft as specified by MIL-L-81174. Various embodiments are described herein with respect to MIL-L-81174 solely for purposes of example and illustration. It is contemplated that the principles of the invention may be similarly applied with respect to other standards and specifications or independent of any particular standard or specification.

Solely by way of example, one of ordinary skill in the art will appreciate that a large percentage of aircraft such as, for example, helicopters, are built with a standard “keyhole slot” operable to accept a MIL-L-81174-compliant searchlight. Searchlights may be used for various purposes including, for example, as searchlights and auxiliary-landing lights. Regardless of any specific type or purpose, MIL-L-81174-compliant searchlights, as noted above, satisfy MIL-L-81174 requirements that include, inter alia, specific requirements for movement (i.e., extension, retraction and rotation), dimensions, and weight. Similarly, a MIL-L-81174-compliant searchlight typically is required to be remotely controlled via an operator control that includes a multi-way switch (e.g., a “top hat” style 4-way or 8-way switch). Table 1 includes a non-exclusive list of MIL-L-81174 requirements.

TABLE 1
Non-Exclusive List of MIL-L-81174 Requirements

Extending limit: Fully extended position shall be not less than 120°
nor more than 130° from the mounting plane of the light.
Braking: Within 0.5° under an air load of 10 pounds whether
extending, retracting, or rotating.
Lamp switching device: A relay or solid state switching device, shall be
provided for controlling the current to the lamp and shall be an integral
part of the light source.
Rotation: The light shall be capable of rotating in both clockwise and
counterclockwise directions, and stopping the light by means of an electric
actuating mechanism, controlled by a remotely situated, eight-position
switch.
Weight: 6 pounds.
Extension time from fully retracted position to fully extended position
shall be 10 seconds maximum with a 10 pound air load applied.
Stowage time from fully extended position to fully retracted position
shall be 10 seconds maximum with a 10 pound air load applied.
Vibration: For −1A and −2A lights only, the vibratory acceleration applied
from 52 to 500 Hz shall be ±5 g instead of ±10 g. The light source shall be on
during the vibration tests and cycled through all switch positions sufficiently
to simulate the conditions anticipated during actual use of the light.
Radio interference: Radio interference tests shall be conducted in accordance
with MIL-STD-461. The light shall be controlled by a MS 28939-1
type switch. However, the switch may be isolated from the test
enclosure (screen room) during the measurements.
Light source cut-off cams: For −1 and −1A lights the cams of the
lights shall be factory adjusted so that the lamp will not be energized
during a rotated position of 90° left to 90° right when the light is
in a position of fully retracted to 60° extended.
Rotation time 360° in both clockwise and counterclockwise directions
shall be 15 seconds maximum and 10 seconds-minimum
(10-1b load not applied).

In various embodiments, thermal-imaging capabilities may be built into a MIL-L-81174-compliant searchlight by including therein a thermal-imaging camera. In various embodiments, the thermal-imaging camera may be steered (e.g., extended, retracted and rotated) using existing, MIL-L-81174-required functionalities of the MIL-L-81174-compliant searchlight and of an aircraft operable to accept the MIL-L-81174-compliant searchlight. An aircraft such as, for example, a helicopter, that includes the standard keyhole slot operable to accept a MIL-L-81174-compliant searchlight may, in a typical embodiment, thereby have remotely-controlled thermal-imaging capabilities.

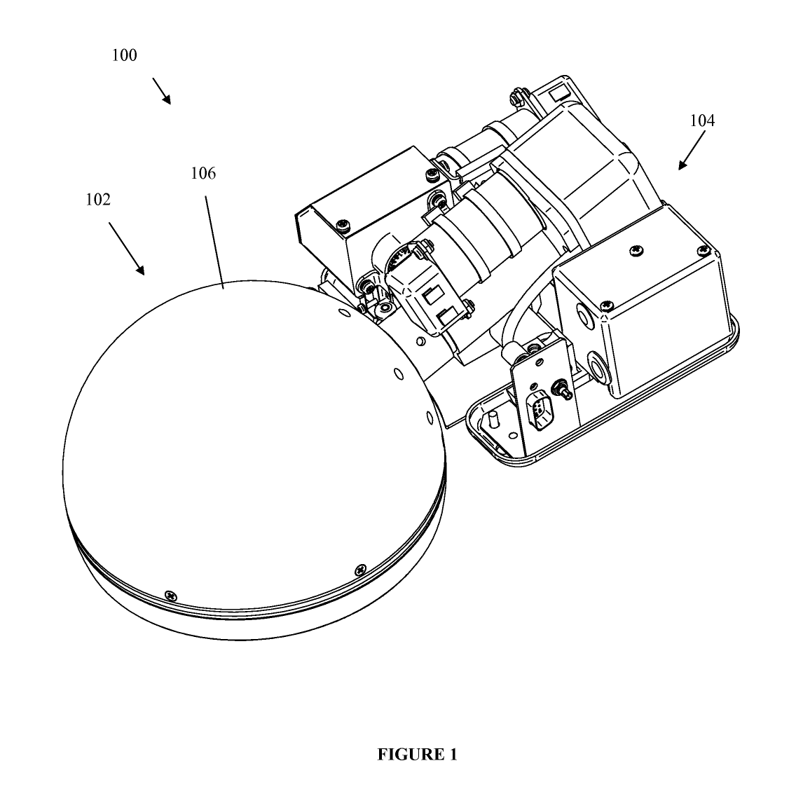

In various embodiments, thermal-imaging capabilities may also be provided in ways that are not directly associated with any particular standard or specification such as, for example, military specification MIL-L-81174. For example, principles of the invention that are utilized, for example, to comply with an envelope required by military specification MIL-L-81174 may also be utilized to build a compact searchlight with similar features that may be used for a variety of purposes. For example, the compact searchlight may be utilized as a handheld unit or integrated with any type of structure such as, for example, a permanent structure or a transport structure (e.g., land-based vehicle, water vessel, or aircraft). FIGS. 1-4 describe illustrative embodiments that may, for example, involve MIL-L-81174-compliant aircraft. In each case, it is contemplated that similar inventive principles may be applied to structures that are not MIL-L-81174-compliant. Additionally, similar inventive principles may be adapted, for example, to a handheld searchlight.

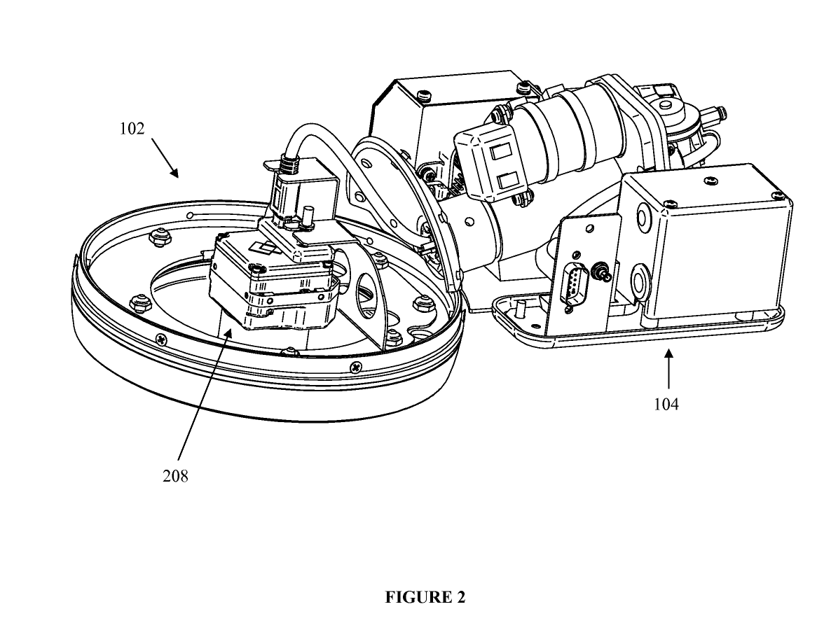

FIG. 1 illustrates a top view of a MIL-L-81174-compliant searchlight 100 according to various embodiments of the invention. The MIL-L-81174-compliant searchlight 100 includes a movable canopy 102 enclosed by a canopy cover 106 and a base 104. The base 104 includes a drive system that, in compliance with MIL-L-81174, is operable to extend, retract and rotate the movable canopy 102 responsive to an operator's control. The operator may be, for example, a driver or pilot of a vehicle. Prior art searchlights typically incorporate a white (i.e., visible) light source and/or an infrared (IR) light source within a movable canopy similar to the movable canopy 102. In various embodiments, as described in more detail with respect to FIG. 2, the movable canopy 102 may include a thermal-imaging camera within the canopy 102 so that, as a result, the thermal-imaging camera may be controlled by the drive system of the base 104 as part of the movable canopy 102.

FIG. 2 depicts the searchlight 100 of FIG. 1 with the canopy cover 106 removed for illustrative purposes. A thermal-imaging camera 208 is shown to be incorporated within the movable canopy 102. By virtue of being included within the movable canopy 102, the thermal-imaging camera 208 may be operated (e.g., extended, retracted, and rotated) by the drive system in the base 104 responsive to an operator's control. In some embodiments and as shown in FIG. 2, the thermal-imaging camera 208 may replace the white light source that is typically present in the prior art searchlights. In these embodiments, this has the advantage of preserving space within the movable canopy 102. However, it is contemplated that, in other embodiments, the thermal-imaging camera and the visible light source may both be enclosed within the movable canopy 102.

In various embodiments, the thermal-imaging camera 208 may be a long-wavelength (8-14 microns) uncooled microbolometer camera designed for infrared imaging applications that demand absolute minimum size, weight, and power consumption. For example, in some embodiments, the thermal-imaging camera 208 may be approximately 44.5 millimeters long, 44.5 millimeters wide, and 30.0 millimeters deep. In other embodiments, the thermal-imaging camera 208 may be approximately 38.1 millimeters long, 38.1 millimeters wide, and 30.0 millimeters deep. In various embodiments, the thermal-imaging camera 208 may weigh less than seventy-two grams and consume less than one watt of power.

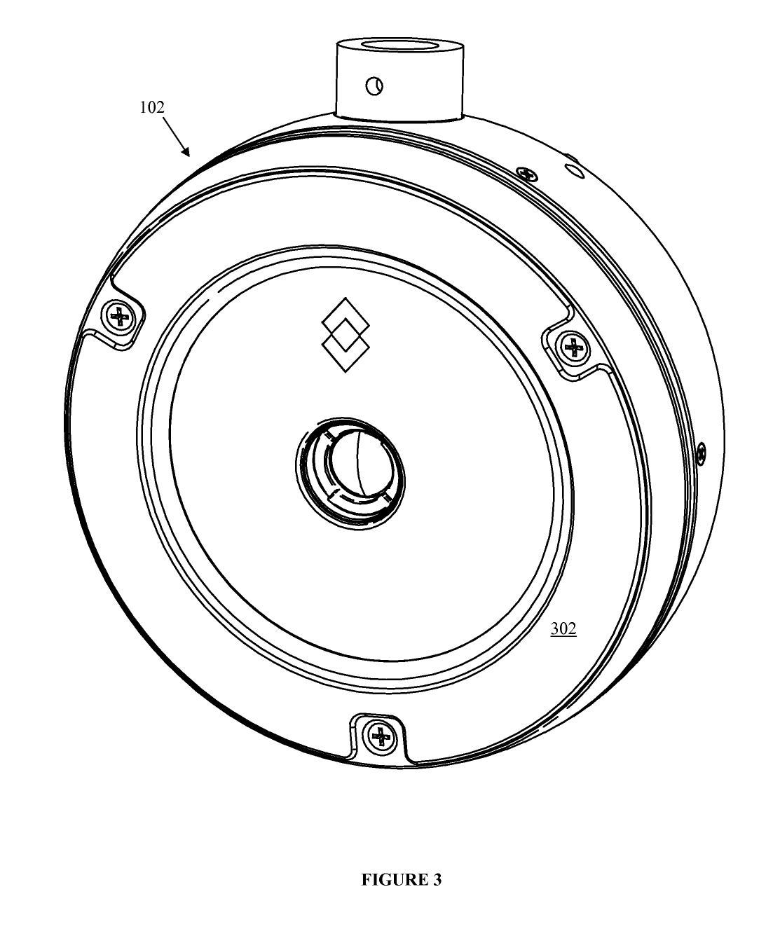

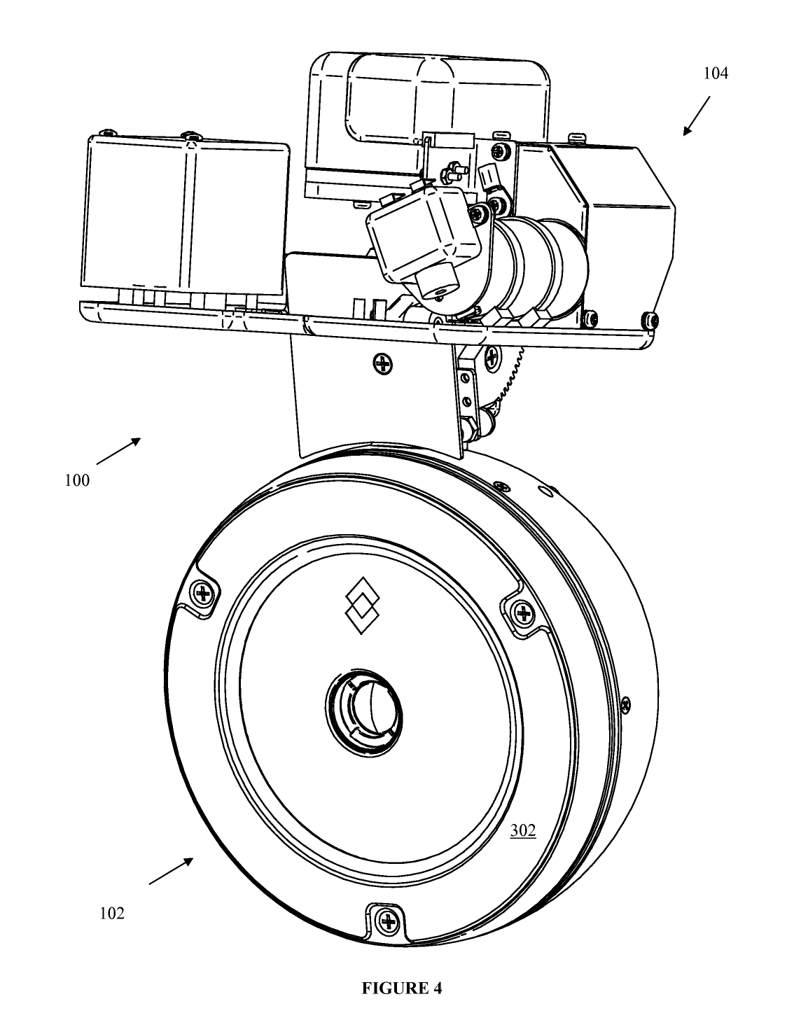

FIG. 3 illustrates a front view of the movable canopy 102 and further depicts an infrared (IR) light source ring 302 along a periphery of the movable canopy 102. In some embodiments, an IR light source such as, for example, the IR light source ring 302, may be installed around a periphery of the movable canopy 102 to support, for example, the use of night-vision goggles. In various other embodiments, it is contemplated that the IR light source ring 302 may not be present. In a typical embodiment, an operator's control allows an operator to individually activate the thermal-imaging camera 208 and the IR light source ring 302 or to simultaneously activate both. A front view of the movable canopy 102 attached relative to the base 104 of the searchlight 100 can be seen in FIG. 4.

In various embodiments, various principles of the invention may also be utilized for non-MIL-L-81174-compliant applications. For example, a searchlight such as, for example, the searchlight 100, may be mated with any type structure such as, for example, a permanent structure or a transport structure (e.g., land-based vehicle, water vessel, or aircraft). In various embodiments, mating the searchlight 100 with non-standard-compliant structures may involve integrating and mounting the searchlight 100 in an individualized manner. For example, in some embodiments, a keyhole slot may be installed on a structure. Additionally, in various embodiments, the searchlight 100 may be adapted to interface with an existing operator control on the structure such as, for example, a 4-way or 8-way switch. In other embodiments, the searchlight 100 may be mounted and coupled with a new operator control specifically for use therewith.

In various embodiments, various principles of the invention may be applied to develop a portable, handheld searchlight. The handheld searchlight may, for example, have functionality similar to that described with respect to the movable canopy 102 depicted in FIG. 3. The handheld searchlight may modify a form factor and exterior design of the movable canopy 102 to accommodate, for example, operator handling and control. For example, the handheld searchlight may include a handle, operator controls, a liquid crystal diode (LCD) display, and other like operator components. The handheld searchlight may be utilized, for example, by military personnel, police officers, public-safety personnel, outdoorsman, and the like. In a typical embodiment, the handheld searchlight is manually steered by an operator so that, as depicted in FIG. 3, no base with a drive system is required.

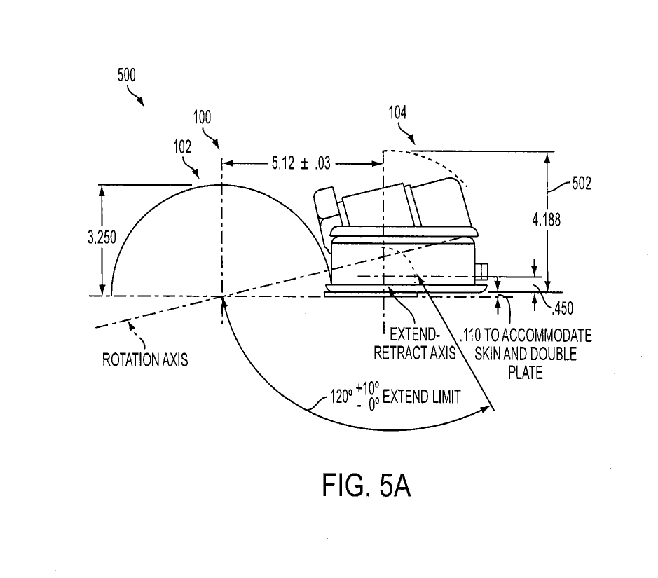

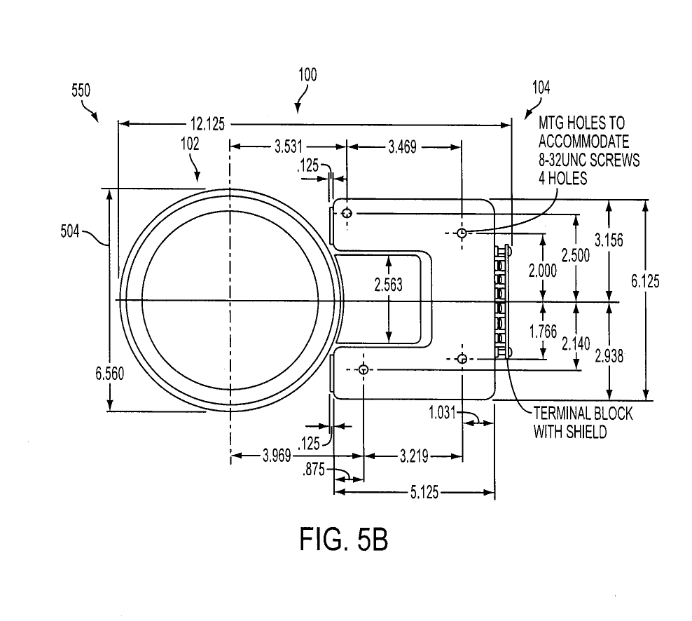

FIG. 5A illustrates a schematic view 500 from a side of the searchlight 100. Various exemplary dimensions of the searchlight 100 are illustrated in inches. One of ordinary skill in the art will appreciate that dimensions illustrated in the schematic view 500 may, in various embodiments, vary depending on a particular application. For example, the schematic view 500 illustrates that the base 104 may have a height 502 of 4.188 inches. In a typical embodiment, the height 502 may advantageously vary within a range, for example, of 3 to 6 inches depending on, for example, necessary functionality and dimensional constraints. One of ordinary skill in the art will appreciate that other dimensions illustrated in the schematic view 500 may advantageously vary in a similar manner.

FIG. 5B illustrates a schematic view 550 of the searchlight 100. Various exemplary dimensions of the searchlight 100 are illustrated in inches. One of ordinary skill in the art will appreciate that dimensions illustrated in the schematic view 550 may, in various embodiments, vary depending on a particular application. For example, the schematic view 550 illustrates that a cross-section of the movable canopy 102 may have a diameter 504 of 6.56 inches. In various embodiments, the diameter 504 may advantageously vary within a range, for example, of 4 to 8 inches depending on, for example, necessary functionality and dimensional constraints. One of ordinary skill in the art will appreciate that other dimensions illustrated in the schematic view 550 may advantageously vary in a similar manner.

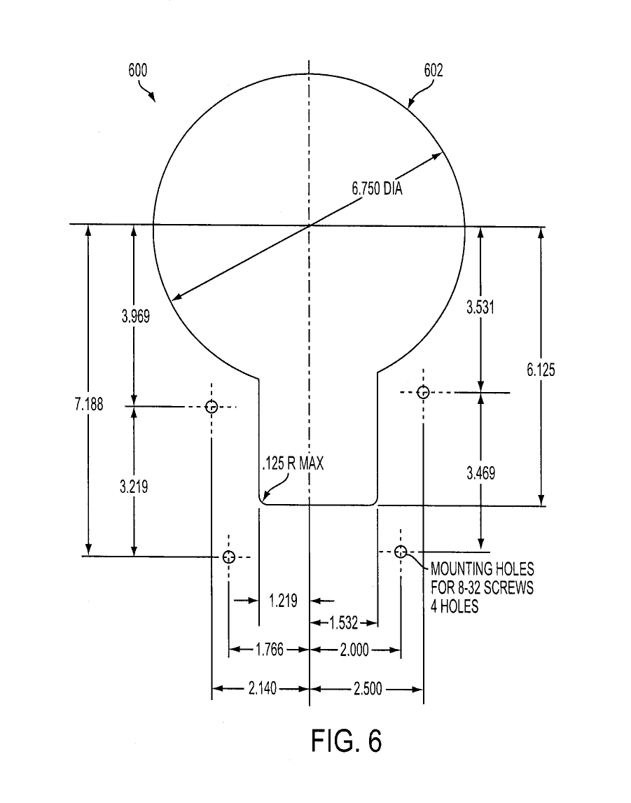

FIG. 6 illustrates a structure 600. The structure 600 may be, for example, a stationary structure or a transport structure. For example, the structure 600 may be any land, water, or air-based vessel or vehicle including, but not limited to, water vessels, aircraft, and land-based vehicles (e.g., tanks, trucks, or cars). The structure 600 may also be any stationary structure including, but not limited to, a port, station or building. The structure 600 includes a keyhole slot 602 with various exemplary dimensions. In a typical embodiment, the searchlight 100 described above with respect to FIGS. 1-5B is operable to mate with the keyhole slot 602 of the structure 600. One of ordinary skill in the art will appreciate that the exemplary dimensions illustrated in FIG. 6 may vary as may be advantageous for particular applications.

Various advantages may be realized through utilization of various embodiments similar to those described above with respect to FIGS. 1-4. Incorporating a thermal-imaging camera such as, for example, the thermal-imaging camera 208, into a searchlight gives operators a lightweight, relatively low-cost option for obtaining thermal-imaging functionality. The searchlight may further include, for example, an IR light source ring such as, for example, the IR light source ring 302.

In a typical embodiment, thermal-imaging and IR capabilities may be made available in a compact, light-weight (e.g., 7 lbs) package for a fraction of the cost, for example, of larger gimbal-mounted thermal-imaging device. Furthermore, in embodiments that utilize an envelope defined by applicable standards such as, for example, MIL-L-81174, a searchlight such as, for example, the searchlight 100 of FIGS. 1-4, is suitable for both new production aircraft and retrofit applications. Additionally, increased use of thermal imaging may assist operators (e.g., pilots of aircraft) in detecting otherwise undetectable threats in low-visibility conditions and thereby improve aircraft safety.

Although various embodiments of the method and apparatus of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth herein.

What is claimed is:

1. A method comprising:
providing a searchlight operable to mate with a structure, the searchlight comprising a base and a canopy movably attached to the base;
mounting a thermal-imaging camera within the canopy so that the thermal-imaging camera is operable to move in conjunction with the canopy responsive to an operator control; and
disposing an infrared (IR) light source ring along a periphery of the canopy.

2. The method of claim 1, the method comprising:
wherein the providing comprises providing a searchlight operable to mate with a structure in compliance with a standard specification;
wherein the standard specification comprises one or more requirements related to each of the following: dimensions of the searchlight, a weight of the searchlight, canopy movement, and control of canopy movement; and
wherein the operability to move utilizes functionality specified by the one or more requirements related to canopy movement and the one or more requirements related to control of canopy movement.

3. The method of claim 2, wherein the mounting comprises replacing a white-light source specified by the standard specification with the thermal-imaging camera.

4. The method of claim 2, wherein the standard specification comprises military specification MIL-L-81174.

5. The method of claim 1, the method comprising:
mating the searchlight to a structure via a keyhole slot, the base comprising a drive system; and
via the drive system, at least one of extending, retracting, and rotating the canopy responsive to the operator control.

6. The method of claim 1, wherein the thermal-imaging camera comprises a long-wavelength uncooled microbolometer camera.

7. The method of claim 1, the method comprising activating the thermal-imaging camera responsive to the operator control.

8. The method of claim 1, the method comprising activating the IR light source ring responsive to the operator control.

9. The method of claim 1, the method comprising simultaneously activating the thermal-imaging camera and the IR light source ring responsive to the operator control.

10. The method of claim 1, wherein the operator control comprises a multi-way switch.

11. The method of claim 1, wherein the structure comprises land-based vehicle.

12. The method of claim 1, wherein the structure comprises water-based vessel.

13. The method of claim 1, wherein the structure comprises stationary structure.

14. The method of claim 1, wherein the structure comprises an aircraft.

15. A searchlight comprising:
a base comprising a drive system, the base operable to mate with a structure;
a canopy movably attached to the base and operable to be controlled by the drive system to move responsive to an operator control;
a thermal-imaging camera mounted within the canopy so that the thermal-imaging camera is operable to move in conjunction with the canopy; and
an infrared (IR) light source ring disposed along a periphery of the canopy.

16. The searchlight of claim 15, wherein:
the base is operable to mate with the structure in compliance with a standard specification;
wherein the canopy is operable to move responsive to the operator control in compliance with the standard specification; and
wherein the standard specification comprises one or more requirements related to each of the following: dimensions of the searchlight, a weight of the searchlight, canopy movement, and operator control of canopy movement.

17. The searchlight of claim 16, wherein the standard specification comprises military specification MIL-L-81174.

18. The searchlight of claim 15, wherein the operability of the canopy to move comprises operability to perform at least one movement selected from the group consisting of: extend, retract, and rotate.

19. The searchlight of claim 15, wherein the thermal-imaging camera comprises a long-wavelength uncooled microbolometer camera.

20. The searchlight of claim 15, wherein the thermal-imaging camera is operable to activate responsive to the operator control.

21. The searchlight of claim 15, wherein the IR light source ring is operable to activate responsive to the operator control.

22. The searchlight of claim 15, wherein the thermal-imaging camera and the IR light source ring are operable to simultaneously activate responsive to the operator control.

23. The searchlight of claim 15, wherein the operator control comprises a multi-way switch.

24. The searchlight of claim 15, wherein the searchlight weighs less than or equal to seven pounds.

25. The searchlight of claim 15, wherein the base is operable to mate with a keyhole slot of the structure.

26. The searchlight of claim 15, wherein the structure comprises land-based vehicle.

27. The searchlight of claim 15, wherein the structure comprises water-based vessel.

28. The searchlight of claim 15, wherein the structure comprises stationary structure.

29. The searchlight of claim 15, wherein the structure comprises an aircraft.

30. A searchlight comprising:
a canopy;
a thermal-imaging camera mounted within the canopy so that the thermal-imaging camera is operable to move in conjunction with the canopy; and
an infrared (IR) light source disposed along a periphery of the canopy.
